(19) United States
(12) Patent Application Publication
(10) Pub. No.: US 2003/0159643 A1
(43) Pub. Date: Aug. 28, 2003

(54) GSO Single crystal and scintillator for PET

(76) Inventors: Keiji Sumiya, Tsukuba-Shi (JP); Hiroyuki Ishibashi, Hitachinaka-Shi (JP); Hideo Murayama, Chiba-Shi (JP); Shigenori Shimizu, Chiba-Shi (JP); Masaaki Kobayashi, Tsukuba-Shi (JP); Mitsuru Ishii, Tokyo (JP)

Correspondence Address: ARMSTRONG,WESTERMAN & HATTORI, LLP, 1725 K STREET, NW, SUITE 1000, WASHINGTON, DC, 20006, US

(21) Appl. No.: 10/357,414

(22) Filed: Feb. 4, 2003

(30) Foreign Application Priority Data
Feb. 5, 2002 (JP) 2002-028698

(51) Int. Cl. C30B 1/00

(52) U.S. Cl. 117/3

(57) ABSTRACT

A Ce-activated GSO single crystal is provided which comprises at least one member selected from the group consisting of Mg, Ta and Zr. The GSO single crystal possesses a faster fluorescence-attenuation time and a smaller output ratio and is colorless and highly transparent. Accordingly, the single crystal may suitably be used as a scintillator for PET.

### BACKGROUND OF THE INVENTION

1. Field of the Invention

The present invention relates to a gadolinium silicon oxide (hereinafter referred to as GSO) single crystal and a scintillator for positron emission computed tomography (hereinafter referred to as PET), which comprises such a GSO single crystal.

2. Description of the Prior Art

In the PET, it is one of the most important factors in the improvement of the overall quality of such a PET device to select quality or specifications of a scintillator to be used in the device. The PET diagnosis has been able to be guaranteed by the insurance with the United States as the central figure and becomes a growing business. Accordingly, there have been conducted vital searches for the development of excellent scintillator materials and studies for the development of growing techniques for putting the same into practical use in order to obtain a high performance PET device.

The GSO scintillator is excellent in the various characteristic properties such as fluorescent output, fluorescence-attenuation time and energy resolution and it is also produced from a material which is excellent in chemical stability, and accordingly, it has been used or adopted as a scintillator for PET. For instance, the energy spectra (¹³⁷Cs) and the emitted light-attenuation curves of two kinds of GSO scintillators having different Ce concentrations are shown in the accompanying FIGS. 1 and 2. From these figures, it is clear that the GSO single crystal scintillator having a Ce concentration of 0.5 mole % is more excellent in the fluorescent output and the energy resolution as compared with that having a Ce concentration of 1.5 mole %. On the other hand, the fluorescence-attenuation time of the latter is shorter (or faster) than that of the former and thus the GSO scintillator having a Ce concentration of 1.5 mole % is more excellent in the fluorescence-attenuation time. This clearly indicates that the Ce concentration would exert inverse influences on the fluorescent output and the fluorescence-attenuation time.

Up to now, it has been pointed out that the conventional GSO single crystal scintillator suffers from various problems detailed below:

(1) The presence of a slow component of emitted light-attenuation curve

The emitted light-attenuation curve of a GSO scintillator shows the presence of two components, that is, a quickly attenuated component (Fast Component) appearing in the range of from 30 to 60 ns and a slowly attenuated component (Slow Component) appearing in the range of from 400 to 600 ns. In this respect, the output ratio of the Slow Component is about 20% and therefore, the presence thereof does not become a serious problem when the GSO scintillator is used in the PET. But it is not preferred for the improvement of the counting rate characteristic properties and there has thus been desired for the reduction of the same.

(2) Coloration due to increase in the Ce concentration

There has been observed slight coloration in pale yellow in a GSO crystal having a Ce concentration of not less than 1.0 mole %. Such coloration is not desirable because of the deterioration of the fluorescent output and energy resolution of the resulting device. FIG. 3 shows the transmittance observed for two kinds of GSO crystals having different Ce concentrations. It is clear from the data plotted on FIG. 3 that the transmittance observed for the GSO crystal having a Ce concentration of 1.5 mole % is lower than that observed for the GSO crystal having a Ce concentration of 0.5 mole %. It would thus be considered that such coloration might be attributable to the presence of tetravalent Ce, which never takes part in the light emission. The GSO crystal is characterized in that the fluorescent light-attenuation time thereof can be shortened by increasing the Ce concentration, but it in turn suffers from a problem in that the fluorescent output is deteriorated. As a method for simultaneously satisfying the requirements for the fluorescence-attenuation time and the fluorescent output, it would be effective to search for impurities, which permit the reduction of the amount of tetravalent Ce present in the GSO crystal.

### SUMMARY OF THE INVENTION

Accordingly, it is an object of the present invention to provide a GSO single crystal whose fluorescence-attenuation time is short, whose output ratio of Slow Component is small and which never undergoes any coloration but has a high transparency.

It is another object of the present invention to provide a scintillator, in particular, a scintillator for PET comprising the GSO single crystal.

The inventors of this invention have conducted various studies to solve the foregoing problems associated with the conventional techniques, have found that a single crystal obtained by adding a small amount of impurities or dopants to a GSO: Ce single crystal (a GSO single crystal containing Ce, i.e., Ce-activated GSO) permits the achievement of the foregoing object of the invention and have thus completed the present invention.

According to an aspect of the present invention, there is provided a Ce-activated GSO single crystal comprising at least one member selected from the group consisting of Mg, Ta and Zr.

The Ce-activated GSO single crystal of the present invention is preferably a single crystal represented by the formula: Gd₍₂₋ₓ₎CeₓMe_{y}SiO₅ wherein x ranges from 0.003 to 0.05, y ranges from 0.00005 to 0.005, and Me represents an element or elements selected from the group consisting of Mg, Ta, Zr and mixtures thereof such as Mg_{z}Zr_{1-z} wherein z ranges from 0 to 1, and more preferably a single crystal represented by the formula: Gd₍₂₋ₓ₎CeₓMg_{y}SiO₅ wherein x ranges from 0.003 to 0.05, and y ranges from 0.00005 to 0.005.

According to a further aspect of the present invention, there is also provided a scintillator for PET comprising the foregoing Ce-activated GSO single crystal.

### BRIEF DESCRIPTION OF THE DRAWINGS

Other objects and features of the present invention will become clear from the following description given below with reference to the accompanying drawings.

FIG. 1A is a graph showing energy spectra observed for a GSO single crystal: (1) GSO: Ce concentration 0.5 mole % (fluorescent output: 486 ch; resolution: 8.26%), and FIG. 1B is a graph showing energy spectra observed for a GSO single crystal: (2) GSO: Ce concentration 1.5 mole % (fluorescent output: 329 ch; resolution: 9.96%).

FIG. 2 is a graph showing an emitted light-attenuation curve observed for a GSO single crystal (fluorescence-attenuation time observed for Ce concentrations of 0.5 mole % and 1.5 mole %: 60 ns and 35 ns, respectively).

FIG. 3 is a graph showing the transmittance (^{t}200 mm) observed for two kinds of GSO single crystals having different Ce concentrations.

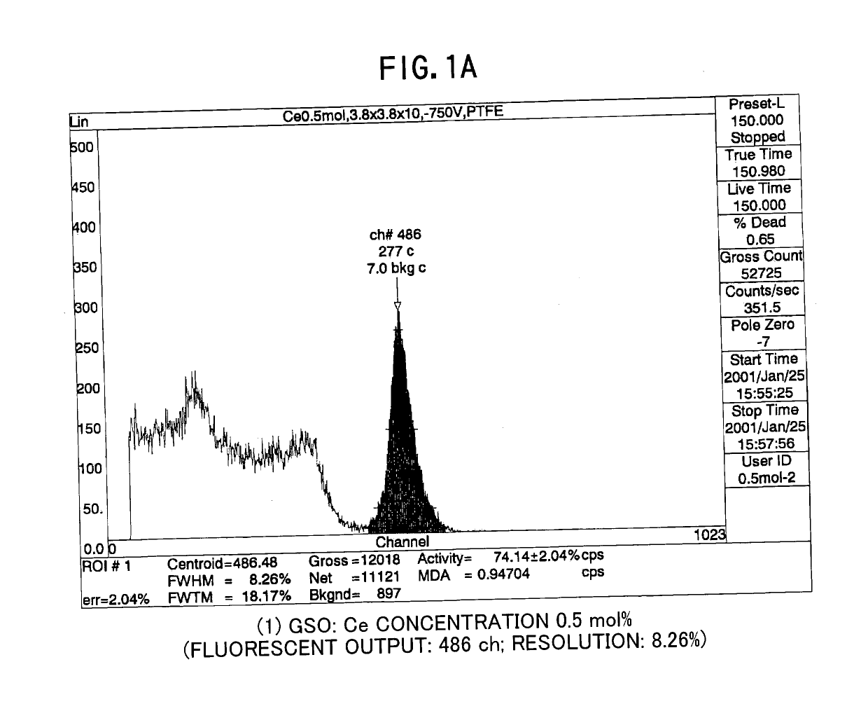

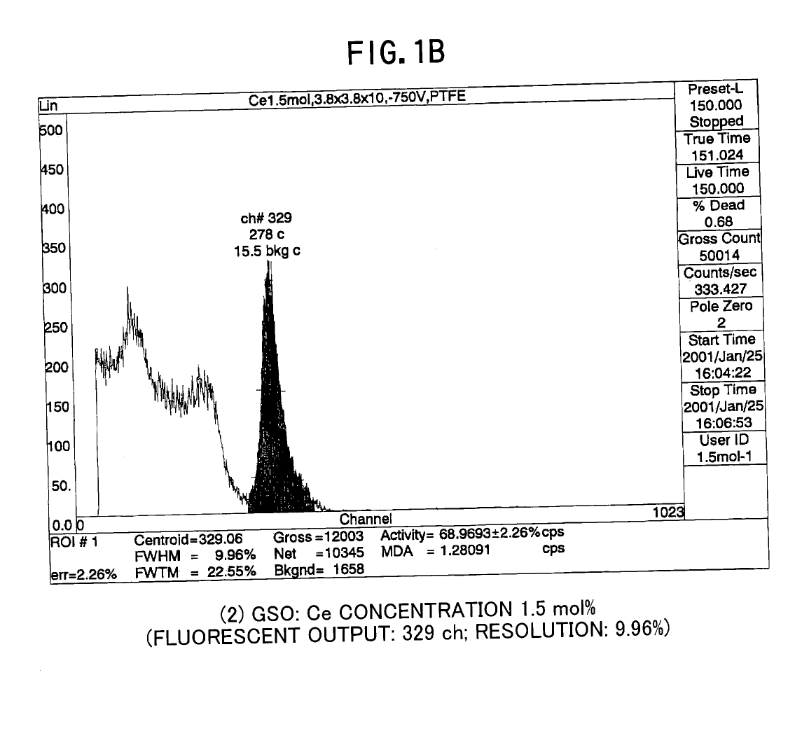

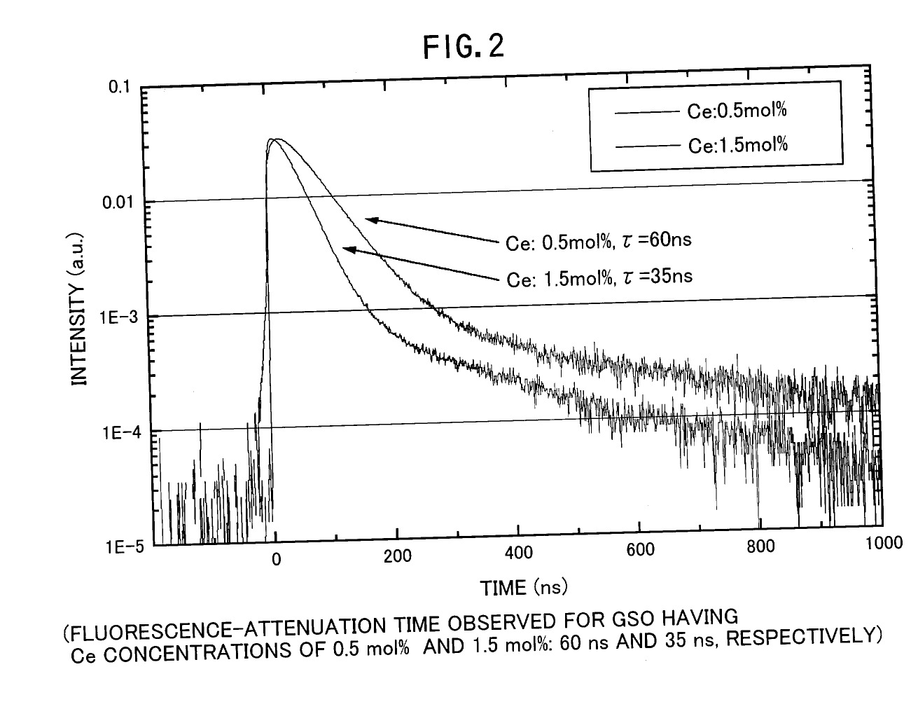

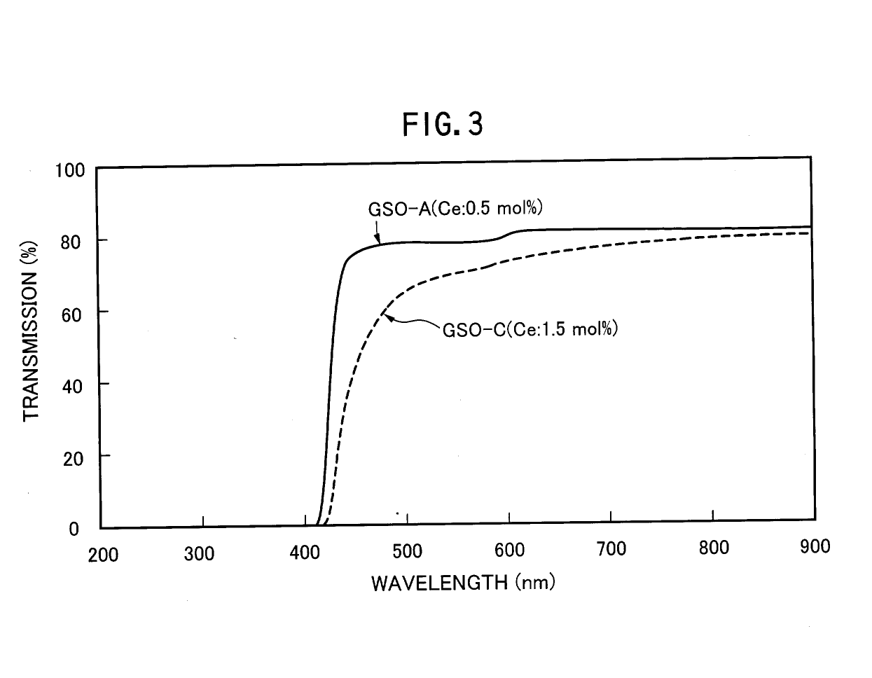

### DESCRIPTION OF THE PREFERRED EMBODIMENTS

The Ce-activated GSO single crystal comprising at least one member selected from the group consisting of Mg, Ta and Zr according to the present invention can, for instance, be produced from a melt comprising gadolinium oxide (Gd₂O₃), silicon oxide (SiO₂), cerium oxide (CeO₂) and at least one metal oxide selected from the group consisting of magnesium oxide (MgO), tantalum(V) oxide (Ta₂O₅), zirconium dioxide (ZrO₂) and complex oxides thereof in such an atomic ratio: Gd=1.95 to 2.0; Si=1.0; Ce=0.003 to 0.05, and Mg, Ta, Zr or mixtures thereof=0.00005 to 0.005, using a seed crystal according to a crystal-growing technique such as Czochralski method.

The atmosphere used in the crystal-growing method is preferably an inert gas (such as nitrogen, helium, neon or argon), which comprises oxygen in an amount ranging from 0.5 to 2.5% by volume. The material for the container such as a crucible used for melting the foregoing materials for the crystal-growth is not restricted to any particular one, but preferably used herein are those having a melting point of not less than 2000° C., with iridium being most preferred.

The molten temperature of the crystalline material used in the crystal-growth step preferably ranges from 1900 to 2000° C. and more preferably 1940 to 1960° C.

The present invention will hereunder be described in more detail with reference to the following working Examples.

There were used as raw materials, gadolinium oxide (Gd₂O₃, purity 99.99% by weight), silicon oxide (SiO₂, purity 99.99% by weight), and cerium oxide (CeO₂, purity 99.99% by weight) and as dopants, magnesium oxide (MgO, purity 99.99% by weight), tantalum(V) oxide (Ta₂O₅, purity 99.99% by weight), and zirconium dioxide (ZrO₂, purity 99.99% by weight) to prepare single crystals according to the Czochralski method. Samples (10 mm×10 mm×10 mm) were taken from the single crystals and were tested for transmittance at 460 nm. Fluorescence-attenuation curves were produced using energy spectra (¹³⁷Cs) and a digital oscilloscope. Fluorescence-attenuation time, output ratios of attenuated components (Fast Component/Slow Component) and fluorescent outputs (relative ratio) are summarized in Table 1. The results are average values of those measured for the upper and lower portions of the single crystal ingots.

These Examples show preferred embodiments of the present invention but do not intend to limit the present invention to these specific Examples at all.

### EXAMPLE 1

### Gd₂SiO₅: Ce, Mg Single Crystal Scintillator

A single crystal doped with Mg was prepared. More specifically, a single crystal was grown from a melt comprising gadolinium oxide (Gd₂O₃), silicon oxide (SiO₂), cerium oxide (CeO₂) and magnesium oxide (MgO) in an atomic ratio: Gd=1.995; Si=1.0; Ce=0.005, Mg=0.002 using a seed crystal according to the Czochralski method at a melt temperature of 1950° C., a pulling rate of 2 mm/hr and a rotational velocity of the seed crystal of 30 rpm. This was a colorless, transparent crystal having a size of about φ25 mm×60 mm. The Ce and Mg concentrations in the single crystal were measured by inductively coupled plasma (hereinafter referred to as ICP) mass spectrometry and found to be 1.5 mole % and 0.0006 to 0.00015 mole %, respectively. The scintillator characteristics of the resulting single crystal are summarized in the following Table 1, while comparing them with the data observed for GSO single crystal grown under the same conditions as those specified above but not containing Mg.

### EXAMPLE 2

### Gd₂SiO₅: Ce, Ta Single Crystal Scintillator

A single crystal doped with Ta was prepared. More specifically, a single crystal was grown from a melt comprising gadolinium oxide (Gd₂O₃), silicon oxide (SiO₂), cerium oxide (CeO₂) and tantalum(V) oxide (Ta₂O₅) in an atomic ratio: Gd=1.995; Si=1.0; Ce=0.005, Ta=0.002 using a seed crystal according to the Czochralski method at a melt temperature of 1950° C., a pulling rate of 2 mm/hr and a rotational velocity of the seed crystal of 30 rpm. This was a colorless, transparent crystal having a size of about φ25 mm×60 mm. The Ce and Ta concentrations in the single crystal were measured by the ICP mass spectrometry and found to be 1.5 mole % and 0.0006 to 0.00015 mole %, respectively. The scintillator characteristics of the resulting single crystal are summarized in the following Table 1, while comparing them with the data observed for GSO single crystal grown under the same conditions as those specified above but not containing Ta.

### EXAMPLE 3

### Gd₂SiO₅: Ce, Zr Single Crystal Scintillator

A single crystal doped with Zr was prepared. More specifically, a single crystal was grown from a melt comprising gadolinium oxide (Gd₂O₃), silicon oxide (SiO₂), cerium oxide (CeO₂) and zirconium dioxide (ZrO₂) in an atomic ratio: Gd=1.995; Si=1.0; Ce=0.005, Zr=0.002 using a seed crystal according to the Czochralski method at a melt temperature of 1950° C., a pulling rate of 2 mm/hr and a rotational velocity of the seed crystal of 30 rpm. This was a colorless, transparent crystal having a size of about φ25 mm×60 mm. The Ce and Zr concentrations in the single crystal were measured by the ICP mass spectrometry and found to be 1.5 mole % and 0.0006 to 0.00015 mole %, respectively. The scintillator characteristics of the resulting single crystal are summarized in the following Table 1, while comparing them with the data observed for GSO single crystal grown under the same conditions as those specified above but not containing Zr.

TABLE 1

| | | Fluores- | | | | Fluores- | |
|---|---|---|---|---|---|---|---|
| | | cence- | | | | cent | Trans- |
| | | Attenuation | | Output Ratio | | Output | mittance |
| | | Time (ns) | | (%) | | (relative | (%) |
| | | Fast | Slow | Fast | Slow | ratio) | at 460 nm |
| | GSO: Ce | 60 | 620 | 81 | 19 | 100 | 82 |
| Ex.1 | GSO: Ce, Mg | 55 | 450 | 90 | 10 | 96 | 81 |
| Ex.2 | GSO: Ce, Ta | 56 | 460 | 87 | 13 | 104 | 81 |
| Ex.3 | GSO: Ce, Zr | 55 | 450 | 88 | 12 | 112 | 82 |

As seen from Table 1, the GSO:Ce single crystals doped with Mg, Ta or Zr as impurities or dopants are colorless and the transmittance thereof is not reduced even if the cerium concentration is about 1.5 mole %. In addition, the output ratio of Slow Component is reduced to about ½ time and the fluorescence-attenuation time is faster than that for the GSO: Ce single crystal by a factor of about ⅓.

As has been described above in detail, the GSO single crystal of the present invention possesses a faster fluorescence-attenuation time and a smaller output ratio and is colorless and highly transparent. Accordingly, the single crystal may suitably be used as a scintillator for PET.

What is claimed is:

1. A Ce-activated GSO single crystal comprising at least one member selected from the group consisting of Mg, Ta and Zr.

2. The GSO single crystal of claim 1 which is represented by the formula: Gd₍₂₋ₓ₎CeₓMe_{y}SiO₅ wherein x ranges from 0.003 to 0.05, y ranges from 0.00005 to 0.005, and Me represents an element or elements selected from the group consisting of Mg, Ta, Zr and mixtures thereof such as Mg_{z}Zr_{1-z} wherein z ranges from 0 to 1.

3. The GSO single crystal of claim 1 which is represented by the formula: Gd₍₂₋ₓ₎CeₓMg_{y}SiO₅ wherein x ranges from 0.003 to 0.05, and y ranges from 0.00005 to 0.005.

4. A scintillator for PET comprising the Ce-activated GSO single crystal as set forth in any one of claims 1 to 3.
